(19) United States
(12) Patent Application Publication
(10) Pub. No.: US 2006/0145317 A1
(43) Pub. Date: Jul. 6, 2006

(54) Leadframe designs for plastic cavity transistor packages

(76) Inventors: John M. Brennan, Wyomissing, NY (US); Patrick J. Carberry, Laurys Station, PA (US); Jeffery J. Gilbert, Schwenksville, PA (US); George John Libricz JR., Bethlehem, PA (US); Ralph S. Moyer, Robesonia, PA (US); John W. Osenbach, Kutztown, PA (US)

Correspondence Address: Law Firm of Peter V.D. Wilde, 301 East Landing, Williamsburg, VA, 23185, US

(21) Appl. No.: 11/029,254

(22) Filed: Dec. 31, 2004

(51) Int. Cl. H01L 21/44; H01L 23/495

(52) U.S. Cl. 257/676; 438/123; 257/669

(57) ABSTRACT

The specification describes a plastic cavity package for semiconductor devices that provides additional mechanical integrity for leads that extend from the plastic housing. Portions of the leads that are within the plastic housing are provided with cutouts. When the plastic housing is formed, or when the cavity is filled with polymer, plastic material fills the cutout, and joins to the mass of plastic on either side of the cutout, thus forming a continuous integral mass of plastic. The end result is that the plastic in the cutout, coupled to the main plastic mass, and to the rigid package sidewall, forms an effective anchor against pulling and bending forces the leads may encounter in manufacture or use.

### FIELD OF THE INVENTION

This invention relates to leadframe designs used in plastic cavity packages for transistors, integrated circuits (ICs), and related devices.

### BACKGROUND OF THE INVENTION

A common form of packaging for electronic devices such as transistor devices is a plastic housing. In the most typical IC plastic package, electronic components are assembled on a metal leadframe and a polymer is molded over the assembly to encapsulate the device. The leadframe serves not only to support the electronic components, but has metal tabs that extend from the overmolded plastic and provide a means to electrically connect to the encapsulated electronic components.

Recent modifications of the molded plastic IC package include an air cavity design wherein the housing for the package is plastic but is pre-molded over a lead frame before the IC device is assembled into the package. This design offers the advantage that the IC chip may be encapsulated with over mold material with a lower dielectric constant than that of the plastic encapsulating the leadframe. Lower dielectric encapsulant materials offer better RF performance. In this design the IC device environment may be an air cavity (the best dielectric constant—1.0), or the cavity may be filled after the IC chip is die attached and wire bonded. The cavity filling may be any polymer, including polymers that cure at low temperatures. The choice of filling material is wider than the choices available in the case of overmolded plastic packages, since the choice is independent of the material used for the pre-molded plastic housing. Thus in a pre-molded plastic cavity package, the IC chip may still be polymer encapsulated, but the dielectric constant of the material maybe chosen for the best RF circuit performance.

Leadframes of the prior art typically are square or rectangular and have a center paddle to which the semiconductor chip is die bonded. Leadframes are typically stamped from copper or copper alloy sheets. The leads that provide electrical interconnection extend from the sides of the paddle, often along two opposing edges of the leadframe. The number of leads may vary widely. Common RF power devices, for example, RFLDMOS devices, may have only a few leads, one per side for each transistor. A typical RFLDMOS package has from 1-4 transistors.

The conventional method for attaching the IC die to the leadframe employs solder as the bonding medium. The specific bonding operation may take a variety of forms. Solder preforms are commonly used. A conventional method for electrically connecting the transistor die to the leads that extend from the sides of the plastic cavity is to use wire bonds from the transistor die to the top surface of the leads. The wire bonds typically are contained within the cavity, and are encapsulated when the cavity is filled with polymer.

In plastic cavity packages with many leads per side, the plastic body that forms the cavity flows around the leads and forms a very integral structure. A leadframe with 10 leads per side for example provides 9 spaces where the plastic joins. If the same space is occupied by only three leads for example, only two spaces where the plastic joins are provided. Thus as the number of leads are reduced, the mechanical integrity of the package may become an issue.

The mechanical integrity issue is especially relevant to the retention forces provided for the leads. A common failure mechanism for these kinds of packages are where the leads are pulled away from the package. Another lead failure mode occurs when the leads are bent on the outside of the package causing a bending moment on the portion of the lead inside the plastic cavity. Even though the wire bonds are protected with polymer filling material, if the bending of the portion of the leads on the outside of the package is severe, the wire bonds may be damaged or broken, especially if the filling material is soft, e.g. silica gel.

### BRIEF STATEMENT OF THE INVENTION

We have developed a leadframe design that provides additional mechanical integrity for the leads in a plastic cavity package. The portions of the leads that are housed either within the walls of the plastic cavity or within the plastic cavity itself are provided with cutouts. When the cavity is molded, or alternatively is filled with polymer, the polymer fills the cutouts, and joins to the mass of plastic fill on either side of the cutouts, thus forming a continuous integral mass of plastic. The end result is that the plastic in the cutouts, coupled to the main plastic mass, and to the rigid package sidewall, forms an effective anchor against pulling and bending forces the leads experience in manufacture or use.

### BRIEF DESCRIPTION OF THE DRAWING

The invention may be better understood when considered in conjunction with the drawing in which:

FIG. 1 is a perspective view of an air cavity plastic package prior to die attachment;

FIG. 2 is a schematic section view through the middle of FIG. 1 after die attachment and wire bonding;

FIG. 3 is a view of the package of FIG. 2, after filling the cavity;

FIG. 4 is a view of the filled cavity package of FIG. 2 illustrating failure modes for the package leads;

FIG. 5 is a plan view of the plastic cavity package after die bonding, wire bonding, and filling, and showing examples of suitable cutouts for anchoring the leads in the package;

FIG. 6 is a section view through 6-6 of FIG. 5;

FIG. 7 shows a preferred embodiment of the invention where the cutouts are formed in the profile of the plastic cavity wall; and

FIG. 8 is a section view through 8-8 of FIG. 7.

### DETAILED DESCRIPTION OF THE INVENTION

The invention will be described in more detail using as a prototypical package a plastic cavity RFLDMOS power transistor package. The invention was developed around this type of package and it represents a preferred embodiment. However, it should be understood that other kinds of IC devices may be packaged using the approach described.

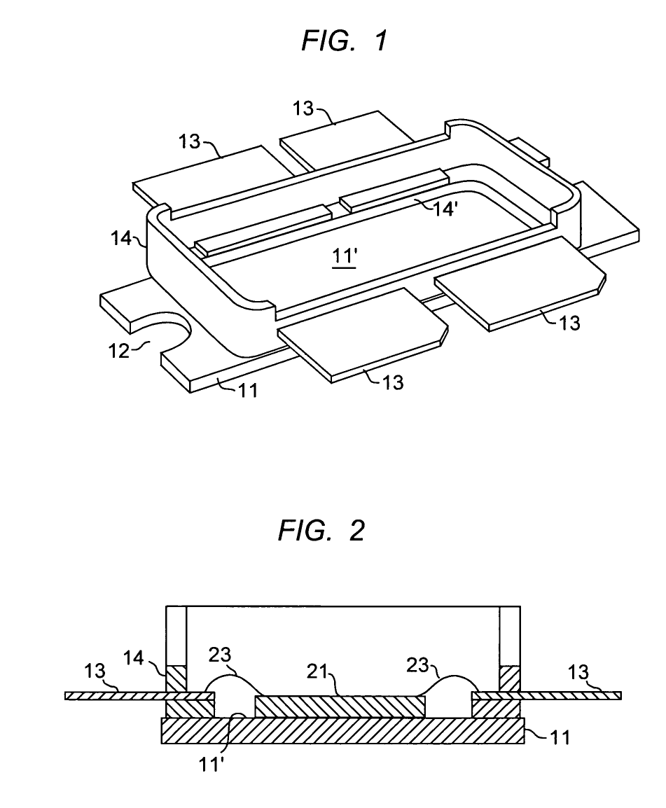

Referring to FIG. 1, a perspective view of a plastic cavity is shown with a metal chip support member 11 comprising at least a portion of what is conventionally considered the lead frame. The metal chip support member 11 is notched at 12 for insertion of a screw or other suitable attachment means to attach the finished IC device to a circuit board or other carrier. This allows the chip support member for the power device to be firmly mounted on the circuit board or on a heat sink, and suitable connectors (not shown) can be attached easily to tab leads 13 on the power device. Molded to the chip support member 11 is a plastic housing 14. The housing comprises four walls and a floor, preferably all comprising an integral body that encloses a cavity. The floor in the center region of the cavity is open, exposing the portion 11′ of the chip support member inside the cavity. The edge of the opening is seen in FIG. 1 at 14′.

The plastic housing is typically insert molded to the chip support member 11 and the leads 13 by a conventional molding/extrusion process. Anchoring methods may be used to increase the integrity of the attachment. For example, tabs or holes may be formed in the chip support member 11 through which the molded plastic penetrates during molding. These act as anchors after the mold compound cures.

The plastic used for the insert molding process may be selected from a wide variety of polymers. It is particularly desirable to choose a material that will result in a plastic body capable of withstanding high temperatures, so as to facilitate a high temperature die attach process.

A main feature of the plastic cavity approach to IC device packaging is that the plastic housing for the package is formed prior to assembling the IC component on the metal support. In the most typical prior art plastic package, the plastic overmolded package, the IC die are attached to a metal lead frame prior to molding the plastic encapsulant around the die and leadframe. This versatile approach has been used to manufacture the vast majority of IC device packages. However, recent trends in IC packaging are toward pre-molded plastic housings, where the plastic housing can be shaped with precision, choice of the material of the plastic housing can be made from a wider selection, the plastic for the housing may be different from the polymer used to encapsulate the IC device, and the IC device after die attach and wirebonding may be encapsulated with a encapsulant with a chosen dielectric constant for a required RF performance.

A section view of FIG. 1 is shown in FIG. 2. The center portion 11′ of the chip support member 11 is shown clearly. The chip support member is typically copper, or a copper alloy. The chip support member, or optionally just the center region 11′ of the chip support member, may be pre-coated with a solder compatible layer. For example, if the solder to be used is a Au—Sn solder, a barrier layer may be applied to the copper chip support member. The barrier layer may be selected from several choices, for example, Ti, Ni, Ta. The barrier layer may be coated with a strike layer of gold.

The IC chip 21 is bonded to the region 11′ of FIG. 2. As described earlier, prior art die bonding operations typically used conventional solder, usually a lead solder. In accordance with recent environmental engineering requirements, most current die bonding operations use lead-free solder. However, other die attach methods may be used.

After die bonding IC chip 21 to the plastic cavity package, the IC chip is connected to leads 13 by wire bonds 23, as shown in FIG. 2.

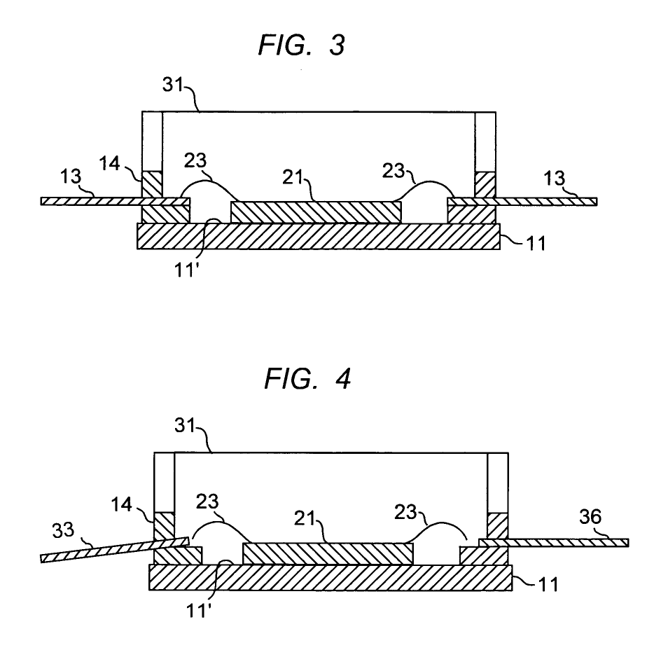

With assembly of the IC device in the plastic cavity completed, the cavity may be filled with a protective fill 31, as shown in FIG. 3. The pre-molded plastic cavity packaging approach offers the advantage that the plastic housing material and the fill material can be independently chosen. For example, the housing material requires a rigid material for mechanical properties of the package where the encapsulant fill material may be a soft pliable material like silicone gel with a selected dielectric constant. The plastic material for the housing can be chosen for mechanical protection, and is typically a high modulus polymer material. The polymer used as the fill material is typically a material having a low dielectric constant to minimize undesirable parasitic effects on device performance. For example, the plastic cavity housing may be a rigid, thermosetting, polymer, for example a liquid crystal polymer (LCP) such as Ticona Vectra S-135. The fill material may be a thermoplastic polymer, such as Loctite Hysol FP-4470.

In the design as shown in FIGS. 1 and 2, the device has two leads extending from each sidewall of the plastic cavity. This particular arrangement is designed for RFLDMOS power transistors. For the arrangement shown there are two transistor devices in the package. In the particular plastic cavity package design of FIGS. 1 and 2, the leads are so-called bayonet leads. They are tab-like in form, and normally are not bent for mounting. In other designs there may be more or fewer (two) leads in all. In some cases a single lead may be split, resulting in four leads, two per side, for a single transistor device. All of these options are intended to be covered by the invention.

A consequence of this design, where tab-like leads are used, is that lateral forces that tend to pull the tab away from the plastic cavity walls, or bend the tab thus distorting the package, are not uncommon. This is described in more detail in conjunction with FIG. 4.

In FIG. 4, the two potential failure modes just mentioned are illustrated. The lead on the left of the figure, lead 33, is shown tilted upward due to excessive bending force. The result is a break in the wire bond to that lead. The lead to the right, lead 36, has been pulled away from the cavity wall by a lateral force. The result, again, is a break in the wire bond to that lead.

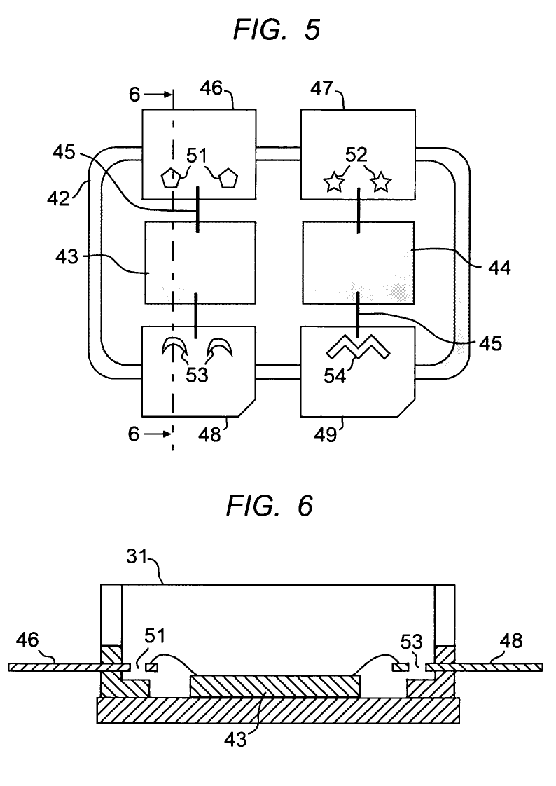

To provide anchoring for the leads, in accordance with the invention, cutouts are formed on the inner portions of the leads, i.e. the portions that reside inside the cavity. In principle, the cutouts may have any shape. However, in the preferred case the cutouts are apertures, defined here as openings through the leads, the openings having a surrounding wall. FIGS. 5 and 6 illustrate typical apertures suitable for anchoring the leads. FIG. 5 shows the plastic cavity package wall at 42. As one example, two RFLDMOS chips 43 and 44 are die bonded to the floor of the cavity, as described earlier. Alternatively, a single die having four interconnecting leads could be used in this package design. In the example shown, the transistor die are interconnected to leads 46, 47, 48, and 49, with wire bonds 45. Alternatives exist for mounting and connecting the die. For example, with suitable modifications in the plastic cavity design, the die may be bump bonded using solder bumps to each of the leads. However, for space efficiency, wire bonds are preferred in the package designs shown here.

Four different forms of cutouts are illustrated in FIG. 5, i.e. 51, 52, 53, and 54. These are shown as illustrative embodiments of the invention. It will be apparent to those skilled in the art that the cutouts may have one or more of a wide variety of shapes. The cutouts extend through the thickness of the leads, as seen more clearly in FIG. 6. FIG. 6 is a section view through 6-6 of FIG. 5. The cutouts form though holes, through which the plastic flows when the plastic cavity 42 is filled. These anchor the leads firmly in the package.

The size of the cutouts in this embodiment is not critical, as long as it is large enough for the polymer fill to flow through from each side and join. The ability of the polymer to flow through the cutout is also a function of the aspect ratio of the cutout. It is recommended that the aspect ratio be at least 1 to ensure flow through. Stated otherwise, the widest dimension of the cutout should be at least equal to the thickness of the lead.

The number of cutouts in each tab lead may vary from one to several or many. An advantage of having two or more cutouts, as compared with a single cutout, is that the anchor is more effective in preventing rotational movement, e.g. movement about the axis of a single cutout.

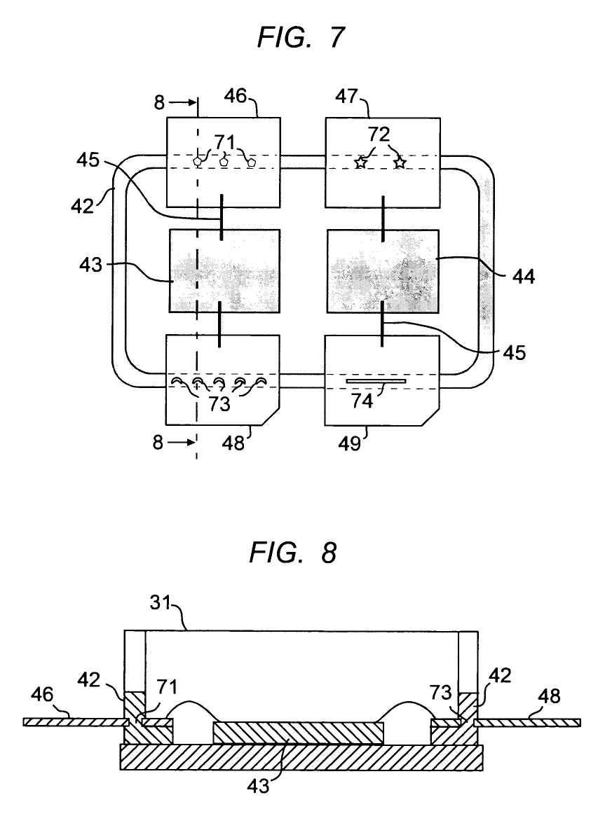

A preferred embodiment of the invention is shown in FIGS. 7 and 8. It should be understood that the polymer material that forms the sidewall of the plastic cavity package is relatively rigid, and strong. As mentioned earlier, typically it has a relatively high elastic modulus. The fill material, 31 in the figures, may have relatively low modulus, and thus relatively low strength. Being a matter of design choice, as also pointed out earlier, the fill material in the practice of the invention may be chosen with a relatively high modulus in order to produce, in combination with the cutouts, an effective anchor. However, recognizing that the walls of the plastic cavity package are already rigid, in the conventional design, the cutouts in the preferred embodiment are placed within the plastic cavity walls. FIG. 7 shows several embodiments of cutouts, 71, 72, 73, and 74, similar the cutouts 51, 52, 53, and 54, of FIG. 5. However, the cutouts are contained, at least in part, in the sidewalls 42. This may be more evident in FIG. 8, which is a section through 8-8 of FIG. 7.

The cutouts will generally be most effective, if contained completely with the sidewalls as shown in these figures. In that case, if the walls have a thickness W, the cutouts will have a maximum width of less than W, and preferably less than 0.9 W. A typical plastic cavity package has a plastic cavity wall thickness of, for example, 0.035″. Thus the widest dimension of the cutouts in this case would be less than 0.035″. The aspect ratio mentioned earlier is easily met since the lead thickness is typically less than 0.01″.

When reference is made herein to the cutout being located within the plastic housing, that reference is to be interpreted as meaning either within the wall of the plastic housing, or inside the cavity. That is, the expression “within the plastic housing” is to be interpreted as generic to the two specific embodiments of the invention that are shown in the figures.

Various additional modifications of this invention will occur to those skilled in the art. All deviations from the specific teachings of this specification that basically rely on the principles and their equivalents through which the art has been advanced are properly considered within the scope of the invention as described and claimed.

1. A plastic cavity package comprising:
(a) leadframe,
(b) a plastic housing attached to the leadframe, the housing comprising four walls and a floor, thereby forming a plastic cavity, the plastic housing having an opening in the floor exposing the leadframe,
(c) a semiconductor device in the plastic cavity, attached to the leadframe,
(d) a plastic fill, the plastic fill filling the plastic cavity and encapsulating the semiconductor device and a portion of the leadframe,
(e) at least two planar tab leads extending through walls of the plastic housing, the tab leads having a portion within the plastic housing and a portion extending outside the plastic housing,
(f) at least one cutout formed in each of the tab leads, the cutout formed in the portion of the tab leads within the plastic housing, the cutouts extending through the thickness of the tab lead, so that the cutout is filled with plastic.

2. The package of claim 1 wherein the cutouts are formed within the boundaries of the walls of the plastic housing.

3. The package of claim 1 wherein the cutouts are formed inside the plastic cavity.

4. The package of claim 1 comprising two to six tab leads.

5. The package of claim 4 wherein each tab lead has at least two cutouts.

6. The package of claim 1 wherein the tab leads have thickness t, and the widest dimension of the cutouts is at least equal to t.

7. The package of claim 2 wherein the walls have a thickness W and the maximum width of the cutouts is less than W.

8. The package of claim 1 wherein the semiconductor device comprises an RFLDMOS device.

9. The package of claim 1 wherein the semiconductor device is connected to the tab leads by wire bonds.

10. A plastic cavity package comprising:
(a) a leadframe,
(b) a plastic housing attached to the leadframe, the housing comprising four walls and a floor, thereby forming a plastic cavity, the plastic housing having an opening in the floor exposing the leadframe,
(c) at least two planar tab leads extending through walls of the plastic housing, the tab leads having a portion within the plastic housing and a portion extending outside the plastic housing,
(d) at least one cutout formed in each of the tab leads, the cutout formed in the portion of the tabs lead within the plastic housing, with the cutout extending through the thickness of the tab lead.

11. A method for the manufacture of a packaged semiconductor device comprising:
(a) attaching a plastic housing to a leadframe, the housing comprising:
(i) four walls and a floor, thereby forming a plastic cavity,
(ii) an opening in the floor exposing the leadframe,
(iii) at least two planar tab leads extending through the walls of the plastic housing, the tab leads having a portion within the plastic housing and a portion extending outside the plastic housing, and at least one cutout formed in each of the tab leads, the cutouts formed in the portion of the tabs lead within the plastic housing, and with the cutouts extending through the thickness of the tab lead,
(b) attaching a semiconductor device to the leadframe in the plastic cavity,
(c) bonding interconnection wires from the semiconductor device to the tab leads,
(d) filling the plastic cavity with plastic fill to encapsulate:
(i′) the semiconductor device,
(ii′) the interconnection wires, and
(iii′) a portion of the leadframe.

12. The method of claim 11 wherein the step of filling the plastic cavity with plastic fill also fills the cutouts.

13. The method of claim 11 wherein the cutouts are located within the boundaries of the walls of the housing.

14. The method of claim 13 wherein the cutouts are filled with plastic during step a.

15. The package of claim 1 wherein the plastic cavity comprises a thermosetting polymer and the plastic fill comprises a thermoplastic polymer.

16. The package of claim 2 wherein the plastic cavity comprises a thermosetting polymer and the plastic fill comprises a thermoplastic polymer.

17. The method of claim 11 wherein the plastic cavity comprises a thermosetting polymer and the plastic fill comprises a thermoplastic polymer.

18. The method of claim 13 wherein the plastic cavity comprises a thermosetting polymer and the plastic fill comprises a thermoplastic polymer.
